(19) United States
(12) Patent Application Publication
(10) Pub. No.: US 2008/0129143 A1
(43) Pub. Date: Jun. 5, 2008

(54) Trimming element and sensor on a single chip

(75) Inventors: James D. Cook, Freeprot, IL (US); James Liu, Londonderry, NH (US); Steven J. Magee, Lena, IL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/633,906

(22) Filed: Dec. 5, 2006

(51) Int. Cl. H02N 2/18; H03H 3/04

(52) U.S. Cl. 310/312; 219/121.68; 438/50

(57) ABSTRACT

An integrated circuit chip has a substrate, an acoustic wave sensor, and a trimming element. The acoustic wave sensor is formed on the substrate, the trimming element is formed on the substrate, and the trimming element is coupled to the acoustic wave sensor so as to trim the acoustic wave sensor when the trimming element is adjusted. The trimming element, for example, may be a trimming capacitor.

### TECHNICAL FIELD

The technical field of this application relates to a chip having both a sensor and a trimming element to trim the sensor.

### BACKGROUND

Trimming is frequently used to adjust the operating parameters (output voltage, frequency, resistance, capacitance, switching threshold, etc.) of an electronic circuit such as an integrated circuit or a printed circuit board. Although other trimming techniques are known, laser trimming is one of the more popular trimming techniques and is implemented to burn away small portions of sensors, resistors, or capacitors to change their characteristics. The burning operation can be conducted while the circuit is being tested by automatic test equipment, leading to extremely accurate final values for the trimmed elements.

The resistance value of a trimmable element is typically defined by its geometric dimensions (length, width, height) and the material used to fabricated the element. A portion of the material forming the trimmable element is removed to change the value of the trimmable element For example, a lateral cut in the resistor material by the laser narrows the current flow path and increases the resistance value. Trimmable chip capacitors are typically build up as multilayer plate capacitors. Vaporizing one or more layers or fingers with a laser decreases the capacitance by reducing the area of the top electrode.

According to current practice, existing wired or wireless acoustic wave sensors such as surface acoustic wave (SAW) sensors and bulk acoustic wave (BAW) sensors packaged on chips are not trimmed. Instead, the characteristics of the sensor are calibrated at multiple points. The calibration data is saved in memory and are used to characterize the sensor's input/output relationship. In many applications, using the chip's real estate for the memory that stores the characteristics of a sensor is costly, and that cost escalates as the number of sensors that are fabricated on the chip increases.

The present invention is directed to an arrangement that solves this or other problems.

### SUMMARY OF THE INVENTION

According to one aspect of the present invention, an integrated circuit chip comprises a substrate, an acoustic wave sensor, and a trimming element. The acoustic wave sensor is formed on the substrate. The trimming element is formed on the substrate, and the trimming element is coupled to the acoustic wave sensor so as to trim the acoustic wave sensor when trimming element is adjusted.

According to another aspect of the present invention, a wireless integrated circuit chip comprises a substrate, an acoustic wave sensor, a trimming element, and an antenna. The acoustic wave sensor is formed on the substrate. The trimming element is formed on the substrate, and the trimming element is coupled to the acoustic wave sensor so as to trim the acoustic wave sensor when the trimming element is adjusted. The antenna is coupled to the acoustic wave sensor.

According to still another aspect of the present invention, a method of forming an integrated circuit chip comprises the following: forming an acoustic wave sensor on a substrate; forming a trimming element on the substrate; and, trimming the trimming element so as to alter a characteristic of the acoustic wave sensor.

### BRIEF DESCRIPTION OF THE DRAWINGS

These and other features and advantages will become more apparent from the detailed description as set out below when taken in conjunction with the drawings in which:

FIG. 1 illustrates one embodiment of a wired or wireless sensor chip having a plurality of acoustic wave sensors and trimming capacitors fabricated thereon;

FIG. 2 illustrates another embodiment of a wired or wireless sensor chip having a plurality of acoustic wave sensors and trimming capacitors fabricated thereon;

FIG. 3 illustrates one form of a capacitor than can be used for each of the trimming capacitors of FIGS. 1 and 2;

FIG. 4 is a cross section of the capacitor shown in FIG. 3; and,

FIG. 5 shows a chip having acoustic wave sensors formed on one side of a substrate, corresponding trimming elements formed on the other side of the substrate, and vias coupling the acoustic wave sensors and their corresponding trimming elements

### DETAILED DESCRIPTION

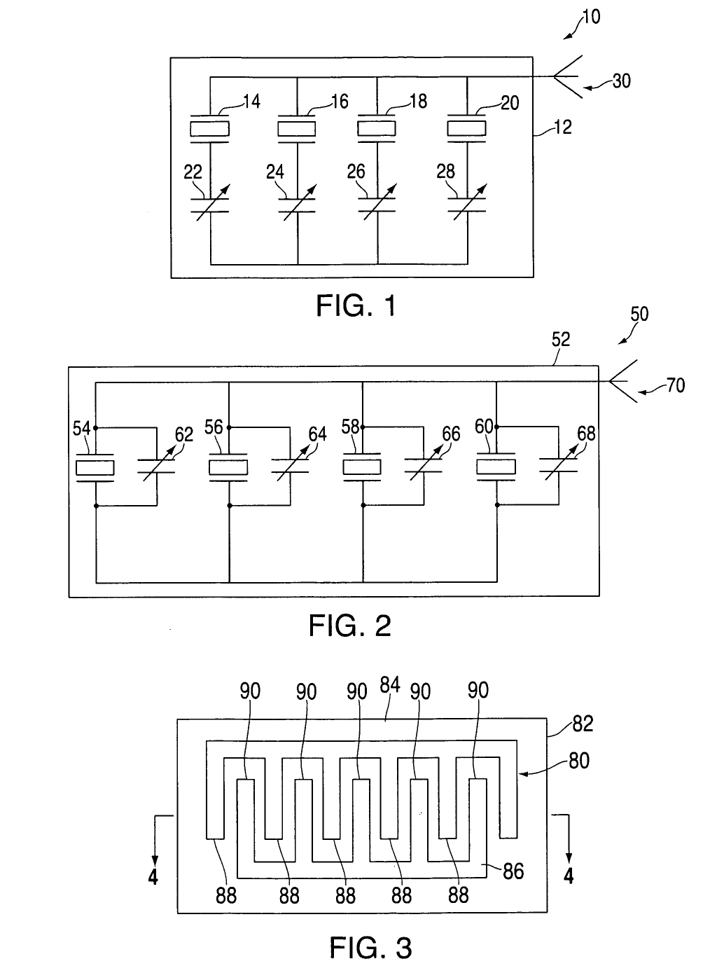

As shown in FIG. 1, a chip 10 has a substrate 12 on which acoustic wave sensors 14, 16, 18, and 20 and trimming capacitors 22, 24, 26, and 28 are formed The acoustic wave sensors 14, 16, 18, and 20 may be surface acoustic wave (SAW) sensors or bulk acoustic wave (BAW) sensors or a combination of surface acoustic wave (SAW) sensors and bulk acoustic wave (BAW) sensors. Additionally or alternatively, the acoustic wave sensors 14, 16, 18, and 20 may be such surface acoustic wave devices as surface acoustic wave resonators (SAW-R), and/or surface acoustic wave delay lines (SAW-DL), and/or surface transverse wave (STW) devices, and/or such other acoustic wave devices as APM (acoustic plate mode) devices, and/or SH-APM (shear-horizontal acoustic plate mode) devices, and/or FPW (flexural plate wave) devices, cantilevered devices, and/or Lamb wave devices, and/or Love wave devices, etc. Additionally, these acoustic wave devices can be provided in a variety of shapes (e.g., circular, square, diamond, rectangular, etc.) and modes (e.g., fundamental and/or overtones).

The substrate 12 could be any of a variety of materials such as piezoelectric, dielectric, or magneto-elastic materials for use as different kind of resonators.

The trimming capacitor 22 is in series with the acoustic wave sensor 14, the trimming capacitor 24 is in series with the acoustic wave sensor 16, the trimming capacitor 26 is in series with the acoustic wave sensor 18, and the trimming capacitor 28 is in series with the acoustic wave sensor 20. The trimming capacitor 22 is adjustable and is provided to trim the acoustic wave sensor 14, the trimming capacitor 24 is adjustable and is provided to trim the acoustic wave sensor 16, the trimming capacitor 26 is adjustable and is provided to trim the acoustic wave sensor 18, and the trimming capacitor 28 is adjustable and is provided to trim the acoustic wave sensor 20.

The trimming capacitors 22, 24, 26, and 28 can be formed on the same side of the substrate 12 as the acoustic wave sensors 14, 16, 18, and 20 Alternatively, the acoustic wave sensors 14, 16, 18, and 20 may be formed on the front side of the substrate 12 and the trimming capacitors 22, 24, 26, and 28 may be formed on the back side of the substrate 12. Laser trimming, if implemented to adjust the values of the trimming capacitors 22, 24, 26, and 28 during trimming of the acoustic wave sensors 14, 16, 18, and 20, could cause is cross-contamination in the case where the acoustic wave sensors 14, 16, 18, and 20 and the trimming capacitors 22, 24, 26, and 28 are formed on the same side of the substrate 12. However, there will be much less cross-contamination if the acoustic wave sensors 14, 16, 18, and 20 are formed on one side of the substrate 12 and the trimming capacitors 22, 24, 26, and 28 are formed on the other side of the substrate 12.

All of the acoustic wave sensors 14, 16, 18, and 20 may be arranged to sense the same condition, such as temperature, humidity, pressure, etc., or each of the acoustic wave sensors 14, 16, 18, and 20 may be arranged to sense a different condition, or a first set of the acoustic wave sensors 14, 16, 18, and 20 may be arranged to sense a first condition, a second different set of the acoustic wave sensors 14, 16, 18, and 20 may be arranged to sense a second different condition, etc., where each set includes one or more of the acoustic wave sensors 14, 16, 18, and 20. Also, while FIG. 1 shows four acoustic wave sensors, the chip 10 may include more or fewer acoustic wave sensors.

In the case where the chip 10 is a wireless chip, the chip 10 has an antenna 30 so that the chip 10 can communicate wirelessly with a remote receiver or transceiver. Although FIG. 1 shows that each of the acoustic wave sensors 14, 16, 1S, and 20 is coupled directly to the antenna 30, the acoustic wave sensors 14, 16, 18, and 20 may be coupled to the antenna 30 through one or more other circuit elements such as multiplexers, and/or amplifiers, and/or comparators, and/or signal conditioning circuits, etc. Thus, FIG. 1 is merely a very high level schematic of the chip 10 to show the relationship between the acoustic wave sensors 14, 16, 18, and 20 and the trimming capacitors 22, 24, 26, and 28. These one or more other circuit elements may also be formed on the substrate 12. Also, the antenna 30 may be formed as a conductive material on the substrate 12 or the antenna 30 may be formed off-chip and coupled to the chip 10.

Furthermore, although the trimming elements that are used to trim the acoustic wave sensors 14, 16, 13, and 20 are shown as the trimming capacitors 22, 24, 26, and 28, other trimming elements such as resistors and/or inductors could be used to trim the acoustic wave sensors 14, 16, 18, and 20. Alternatively, various combinations of resistors, inductors, and/or capacitors could be used to trim the acoustic wave sensors 14, 16, 18, and 20. However, the use of the trimming capacitors 22, 24, 26, and 28 to trim the acoustic wave sensors 14, 16, 18, and 20 has the advantage of providing a high Q.

Laser trimming can be used to adjust the values of the trimming capacitors 22, 24, 26, and 28 so as to trim the acoustic wave sensors 14, 16, 18, and 20. For example, if the trimming capacitors 22, 24, 26, and 28 are fabricated on the substrate 12 as electrodes having interlaced fingers, one or more of the fingers can be severed or shortened by a laser to provide a desired amount of trimming.

As shown in FIG. 2, a chip 50 has a substrate 52 on which acoustic wave sensors 54, 56, 58, and 60 and trimming capacitors 62, 64, 66, and 68 are formed. The acoustic wave sensors 54, 56, 58, and 60 may be surface acoustic wave (SAW) sensors or bulk acoustic wave (BAW) sensors or a combination of surface acoustic wave (SAW) sensors and bulk acoustic wave (BAW) sensors. Additionally or alternatively, one or more of the acoustic wave sensors 54, 56, 58, and 60 may be such surface acoustic wave devices as surface acoustic wave resonators (SAW-R), and/or surface acoustic wave delay lines (SAW-DL), and/or surface transverse wave (STW) devices, and/or such other acoustic wave devices as APM (acoustic plate mode) devices, and/or SH-APM (shear-horizontal acoustic plate mode) devices, and/or FPW (flexural plate wave) devices, and/or cantilevered devices, and/or Lamb wave devices, and/or Love wave devices, etc. Additionally, these acoustic wave devices can be provided in a variety of shapes (e.g., circular, square, diamond, rectangular, etc.) and modes (e.g., fundamental and/or overtones).

The trimming capacitor 62 is in parallel with the acoustic wave sensor 54, the trimming capacitor 64 is in parallel with the acoustic wave sensor 56, the trimming capacitor 66 is in parallel with the acoustic wave sensor 58, and the trimming capacitor 68 is in parallel with the acoustic wave sensor 60. The trimming capacitor 62 is adjustable and is provided to trim the acoustic wave sensor 54, the trimming capacitor 64 is adjustable and is provided to trim the acoustic wave sensor 56, the trimming capacitor 66 is adjustable and is provided to trim the acoustic wave sensor 58, and the trimming capacitor 68 is adjustable and is provided to trim the acoustic wave sensor 60.

All of the acoustic wave sensors 54, 56, 58, and 60 may be arranged to sense the same condition, such as temperature, humidity, pressure, etc., or each of the acoustic wave sensors 54, 56, 58, and 60 may be arranged to sense a different condition, or a first set of the acoustic wave sensors 54, 56, 58, and 60 may be arranged to sense a first condition, a second different set of the acoustic wave sensors 54, 56, 58, and 60 may be arranged to sense a second different condition, etc., where each set includes one or more of the acoustic wave sensors 54, 56, 58, and 60. Also, while FIG. 1 shows four acoustic wave sensors, the chip 50 may include more or fewer acoustic wave sensors.

The chip 50 has an antenna 70 so that the chip 50 can communicate wirelessly with a remote receiver or transceiver. Although FIG. 2 shows that each of the acoustic wave sensors 54, 56, 58, and 60 is coupled directly to the antenna 70, the acoustic wave sensors 54, 56, 58, and 60 may be coupled to the antenna 70 through one or more other circuit elements such as multiplexers, and/or amplifiers, and/or comparators, and/or signal conditioning circuits, etc. Thus, FIG. 2 is merely a very high level schematic of the chip 50 to show the relationship between the acoustic wave sensors 54, 56, 58, and 60 and the trimming capacitors 62, 64, 66, and 68. These one or more other circuit elements may also be formed on the substrate 52. Also, the antenna 70 may be formed as a conductive material on the substrate 52 or the antenna 70 may be formed off-chip and coupled to the chip 50.

Furthermore, although the trimming elements that are used to trim the acoustic wave sensors 54, 56, 58, and 60 are shown as the trimming capacitors 62, 64, 66, and 68, other trimming elements such as resistors and/or inductors could be used to trim the acoustic wave sensors 54, 56, 58, and 60. Alternatively, various combinations of resistors, inductors, and/or capacitors could be used to trim the acoustic wave sensors 54, 56, 58, and 60. However, the trimming capacitors 62, 64, 66, and 68 to trim the acoustic wave sensors 54, 56, 58, and 60 has the advantage of providing a high Q.

Laser trimming can be used to adjust the values of the trimming capacitors 62, 64, 66, and 68 so as to trim the acoustic wave sensors 54, 56, 58, and 60. For example, if the trimming capacitors 62, 64, 66, and 68 are fabricated on the substrate 52 as electrodes having interlaced fingers, one or more of the fingers can be severed or shortened by a laser to provide a desired amount of trimming.

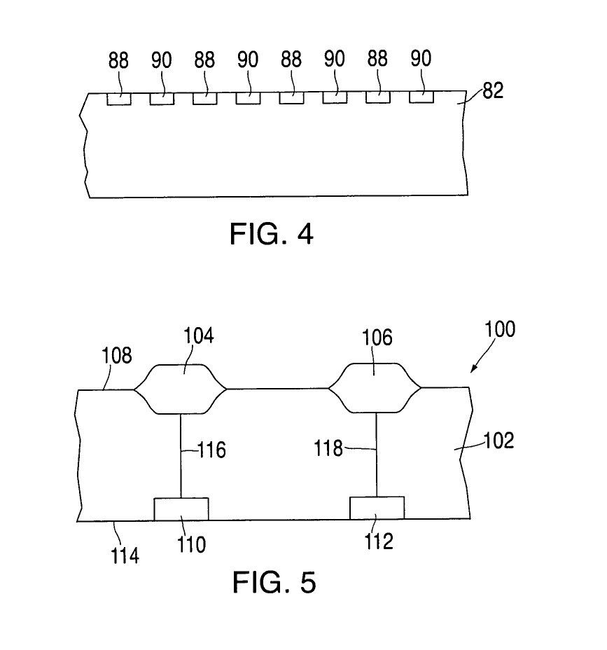

Each of the trimming capacitors 22, 24, 26, 28, 62, 64, 66, and 68 may take the form of a capacitor 80, which is shown in FIGS. 3 and 4. As shown in FIGS. 3 and 4, the capacitor 80 is formed on a substrate 82. The substrate 82, for example, may be either the substrate 12 or the substrate 52. The capacitor 80 has electrodes 84 and 86- The electrodes 84 and 86 are formed from a conductive material during a process, such as a metallization process. The electrode 84 has fingers 88 that interlace with fingers 90 of the electrode 86. The dielectric of the substrate 82 provides the dielectric of the capacitor 80 and, as shown FIGS. 3 and 4, is between the electrodes 84 and 86 and between the fingers 88 and 90 of the electrodes 84 and 86.

One or more fingers of the electrode 84 and/or the electrode 86 may be fully or partially vaporized by use of a laser in order to adjust the capacitance of the capacitor 80 so as to trim the acoustic sensor with which the capacitor 80 is associated.

Many physical acoustic wave sensors are relatively easier to trim by traditional telecom procedures. However, acoustic wave chemical and bio-chemical sensors when formed at the wafer lever are much more difficult to trim using the traditional procedures because of the chemical and bio material coatings used with such devices Traditional trimming of such devices is hard to control, can cause huge changes in frequency, and/or can reduce the Q of the sensor. Hence, in these cases, performance is substantially degraded. The use of a dedicated trimming capacitor solves these kinds of issues.

Certain modifications of the present invention have been discussed above. Other modifications of the present invention will occur to those practicing in the art of the present invention. For example, as suggested above, laser trimming can be used to adjust the values of the trimming elements so as to trim the acoustic wave sensors. However, techniques other than laser trimming can instead be used to adjust the values of the trimming elements so as to trim the acoustic wave sensors.

Also, the trimming elements are shown as being connected directly to the acoustic wave sensors. However, the trimming elements may be coupled to the acoustic wave sensors through one or more various circuit elements.

In addition, FIG. 3 illustrates one example of a capacitor than can be used for the trimming capacitors of FIGS. 1 and 2. However, other forms of capacitors can be used for the trimming capacitors of FIGS. 1 and 2.

Moreover, as discussed, a laser can be used vaporize one or more fingers of the electrode 84 and/or the electrode 86 either fully or partially in order to adjust the capacitance of the capacitor 80 so as to trim the acoustic sensor with which the capacitor 80 is associated. However, techniques other than laser trimming can instead be used to adjust the capacitor 80 so as to trim the associated acoustic wave sensor.

Furthermore, as described above, acoustic wave sensors may be formed on one side of a substrate and their corresponding trimming elements may be formed on the other side of the substrate. In this case, vias may be provided through the substrate to couple the acoustic wave sensors and their corresponding trimming elements together in any of the arrangements described above.

Such a chip is shown in FIG. 5 as a chip 100 having a substrate 102. Acoustic wave sensors 104 and 106 are formed on a first side 108 of the substrate 102, and trimming capacitors 110 and 112 are formed on a second side 114 of the substrate 102. A via 116 is provided through the substrate 102 to couple the acoustic wave sensor 104 to the trimming capacitor 110, and a via 118 is provided through the substrate 102 to couple the acoustic wave sensor 106 to the trimming capacitor 112. As indicated above, these couplings may be series or parallel couplings. As also indicated above, there may be more or fewer combinations of acoustic wave sensors and trimming elements. The first and second sides 108 and 114, for example, may be opposing sides of the substrate 102.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

What is claimed is:

1. An integrated circuit chip comprising:
a substrate;
an acoustic wave sensor formed on the substrate; and,
a trimming element formed on the substrate, wherein the trimming element is coupled to the acoustic wave sensor so as to trim the acoustic wave sensor when trimming element is adjusted.

2. The integrated circuit chip of claim 1 wherein the acoustic wave sensor comprises a first acoustic wave sensor, wherein the trimming element comprises a first trimming element, wherein the integrated circuit chip comprises a second acoustic wave sensor and a second trimming element, wherein the first trimming element is coupled to the first acoustic wave sensor so as to trim the first acoustic wave sensor when the first trimming element is adjusted, and wherein the second trimming element is coupled to the second acoustic wave sensor so as to trim the second acoustic wave sensor when the second trimming element is adjusted.

3. The integrated circuit chip of claim 2 wherein the first acoustic wave sensor is arranged to sense a first condition, and wherein the second acoustic wave sensor is arranged to sense a second condition different than the first condition.

4. The integrated circuit chip of claim 2 wherein the first trimming element comprises a first trimming capacitor, and wherein the second trimming element comprises a second trimming capacitor.

5. The integrated circuit chip of claim 1 wherein the trimming element comprises a trimming capacitor.

6. The integrated circuit chip of claim 1 wherein the acoustic wave sensor and the trimming element are coupled substantially in series.

7. The integrated circuit chip of claim 1 wherein the acoustic wave sensor and the trimming element are coupled substantially in parallel.

8. The integrated circuit chip of claim 1 wherein the acoustic wave sensor and the trimming element are formed on different sides of the substrate.

9. A wireless integrated circuit chip comprising:
a substrate;
an acoustic wave sensor formed on the substrate;
a trimming element formed on the substrate, wherein the trimming element is coupled to the acoustic wave sensor so as to trim the acoustic wave sensor when the trimming element is adjusted; and,
an antenna coupled to the acoustic wave sensor.

10. The wireless integrated circuit chip of claim 9 wherein the acoustic wave sensor comprises a first acoustic wave sensor, wherein the trimming element comprises a first trimming element, wherein the integrated circuit chip comprises a second acoustic wave sensor and a second trimming element, wherein the first trimming element is coupled to the first acoustic wave sensor so as to trim the first acoustic wave sensor when the first trimming element is adjusted, wherein the second trimming element is coupled to the second acoustic wave sensor so as to trim the second acoustic wave sensor when the second trimming element is adjusted, and wherein the antenna is coupled to the first and second acoustic wave sensors.

11. The wireless integrated circuit chip of claim 10 wherein the first acoustic wave sensor is arranged to sense a first condition, and wherein the second acoustic wave sensor is arranged to sense a second condition different than the first condition.

12. The wireless integrated circuit chip of claim 10 wherein the first trimming element comprises a first trimming capacitor, and wherein the second trimming element comprises a second trimming capacitor.

13. The wireless integrated circuit chip of claim 9 wherein the trimming element comprises a trimming capacitor.

14. wireless The integrated circuit chip of claim 9 wherein the acoustic wave sensor and the trimming element are coupled substantially in series.

15. The wireless integrated circuit chip of claim 9 wherein the acoustic wave sensor and the trimming element are coupled substantially in parallel.

16. The wireless integrated circuit chip of claim 9 wherein the acoustic wave sensor and the trimming element are formed on different sides of the substrate.

17. A method of forming an integrated circuit chip comprising:
forming an acoustic wave sensor on a substrate;
forming a trimming element on the substrate; and,
trimming the trimming element so as to alter a characteristic of the acoustic wave sensor.

18. The method of claim 17 wherein the forming of a trimming element on the substrate comprises forming a trimming capacitor on the substrate, and wherein the trimming of the trimming element so as to alter a characteristic of the acoustic wave sensor comprises trimming the trimming capacitor so as to alter a characteristic of the acoustic wave sensor.

19. The method of claim 18 wherein the trimming of the trimming capacitor so as to alter a characteristic of the acoustic wave sensor comprises vaporizing a portion of an electrode of the trimming capacitor.

20. The method of claim 17 wherein the forming of an acoustic wave sensor on a substrate comprises forming an acoustic wave sensor on a first side of the substrate, wherein the forming of a trimming element on the substrate comprises forming a trimming element on a second side of the substrate, and wherein the first and second sides are different sides of the substrate.

21. The method of claim 17 wherein the forming of an acoustic wave sensor on a substrate comprises forming a first acoustic wave sensor on the substrate, wherein the forming of a trimming element on the substrate comprises forming a first trimming capacitor on the substrate, wherein the method further comprises forming a second acoustic wave sensor and a second trimming element on the substrate, and wherein the trimming of the trimming element so as to alter a characteristic of the acoustic wave sensor comprises:
trimming the first trimming element so as to alter a characteristic of the first acoustic wave sensor; and,
trimming the second trimming element so as to alter a characteristic of the second acoustic wave sensor.

22. The method of claim 21 wherein the forming of a first trimming element on the substrate comprises forming a first trimming capacitor on the substrate, wherein the forming of a second trimming element on the substrate comprises forming a second trimming capacitor on the substrate, wherein the trimming of the first trimming element so as to alter a characteristic of the first acoustic wave sensor comprises trimming the first trimming capacitor so as to alter a characteristic of the first acoustic wave sensor, and wherein the trimming of the second trimming element so as to alter a characteristic of the second acoustic wave sensor comprises trimming the second trimming capacitor so as to alter a characteristic of the second acoustic wave sensor.

23. The method of claim 22 wherein the trimming of the first trimming capacitor so as to alter a characteristic of the first acoustic wave sensor comprises vaporizing a portion of an electrode of the first trimming capacitor, and wherein the trimming of the second trimming capacitor so as to alter a characteristic of the second acoustic wave sensor comprises vaporizing a portion of an electrode of the second trimming capacitor.

24. The method of claim 17 further comprising forming an antenna coupled to the acoustic wave sensor.
